(19) United States
(12) Patent Application Publication
(10) Pub. No.: US 2026/0344347 A1
(43) Pub. Date: Oct. 29, 2026

(54) FRONT OPENING UNIFIED POD (FOUP) AND CONTROLLING METHOD THEREOF

(71) Applicant: Taiwan Semiconductor Manufacturing Company, Ltd., Hsinchu (TW)

(72) Inventors: Jyh-Shiou HSU, Hsinchu (TW); Chyi-Tsong NI, Hsinchu (TW); Chao-Po LU, Hsinchu (TW); Jeng-Shin MA, Hsinchu (TW)

(73) Assignee: Taiwan Semiconductor Manufacturing Company, Ltd., Hsinchu (TW)

(21) Appl. No.: 19/188,369

(22) Filed: Apr. 24, 2025

(51) Int. Cl. H10P 72/10

(52) U.S. Cl. CPC H10P 72/1924

(57) ABSTRACT

A front opening unified pod (FOUP) and a controlling method thereof are provided. The FOUP comprises a container, a diffuser and a purge port. The container is configured to carry a plurality of wafers. The diffuser is disposed inside the container. The purge port is disposed in a bottom plane of the container. The purge port has a buffer room. The diffuser is fully overlapped with the buffer room.

### BACKGROUND

The disclosure relates in general to a tool and a controlling method thereof, and more particularly to a front opening unified pod (FOUP) and a controlling method thereof.

In the semiconductor manufacturing, uncontrolled humidity can cause oxidation, corrosion, photoresist issues, wafer warpage, plasma process instability and/or defects in deposition. Particle can cause yield loss, pattern defects, process non-uniformity, and/or electrical failures.

Even sub-micron levels of contamination can lead to defects, yield loss, and reliability issues in advanced semiconductor devices. Therefore, maintaining strict humidity control and minimizing particle contamination is critical for semiconductor wafer processing.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a load port and a front opening unified pod (FOUP) according to one embodiment of the present disclosure.

FIG. 2 shows a stereoscopic view of the FOUP according to one embodiment of the present disclosure.

FIG. 3 shows a cross-section view of the FOUP according to one embodiment of the present disclosure.

FIG. 4 shows an enlarged view of a diffuser and a purge port of the FOUP according to one embodiment of the present disclosure.

FIG. 5 shows a top view of the diffuser and the buffer room of the FOUP.

FIG. 6 shows a back pressure curve for a FOUP without a straight air flow channel and a back pressure curve for the FOUP with the straight air flow channel.

FIG. 7 shows humidity control for different FOUPs.

FIG. 8 shows a flowchart of a controlling method for the FOUP.

FIG. 9 shows an enlarged view of the diffuser and the buffer room according to another embodiment of the present disclosure.

FIG. 10 shows a top view of the diffuser and the buffer room according to another embodiment of the present disclosure.

FIG. 11 shows an enlarged view of the diffuser and the buffer room according to another embodiment of the present disclosure.

FIG. 12 shows a top view of the diffuser and the buffer room according to another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “comprise,” “comprising,” “include,” “including,” “has,” “having,” etc. used in this specification are open-ended and mean “comprises but not limited.” The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

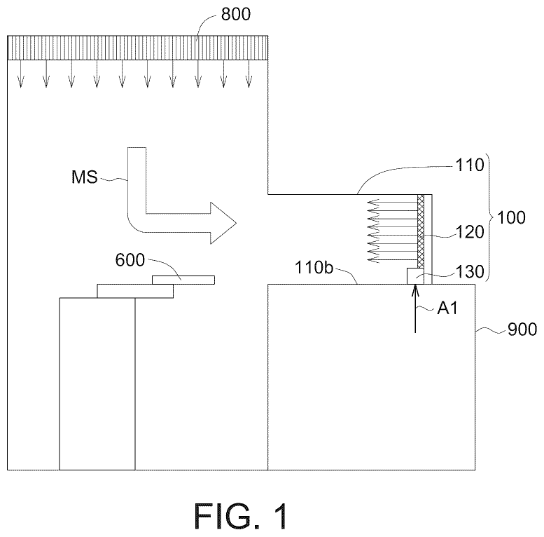

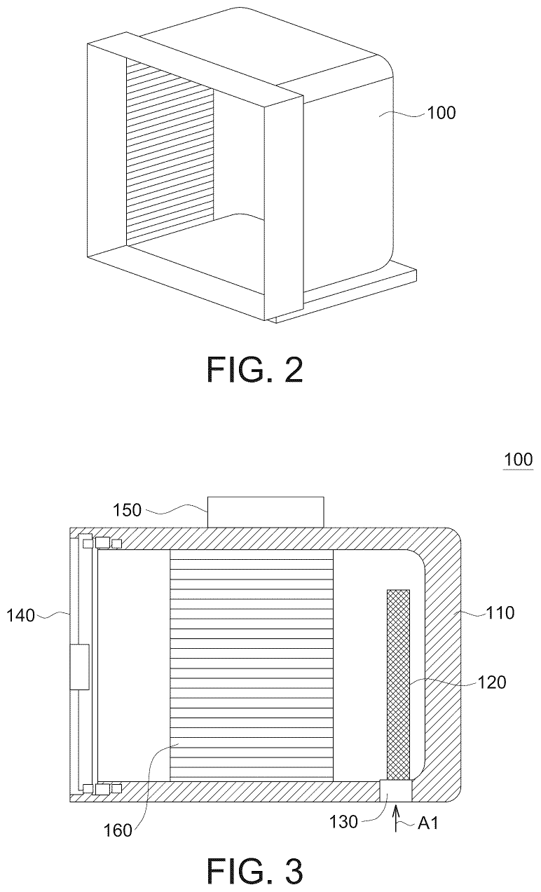

Please refer to FIGS. 1 and 2. FIG. 1 shows a load port 900 and a front opening unified pod (FOUP) 100 according to one embodiment of the present disclosure. FIG. 2 shows a stereoscopic view of the FOUP 100 according to one embodiment of the present disclosure. In the semiconductor manufacturing, wafers are transferred from the FOUP 100 to a process chamber through specialized handling systems designed for automation, precision, and contamination control.

The wafer transfer flow includes the following steps. The FOUP 100 docks at the load port 900. Then, the load port 900 opens the FOUP 100. Next, a wafer handling robot 600 picks the wafer. Afterwards, the wafer moves through an aligner station. Then, the wafer enters a transfer module (ATM or VTM). Next, the wafer is placed inside the process chamber. During transferring the wafer, the FOUP 100 is opened and the moisture MS easily enters to the FOUP 100.

The load port 900 is, for example, an ASML load port for lithography tools, or an AMAT (Applied Materials) load ports for etch & deposition. The wafer handling robot is, for example, a brooks automation wafer handling robot, or a Kawasaki & Rorze semiconductor robot. The transfer module is, for example, an AMAT Centura & Endura transfer module or a Tokyo Electron (TEL) VTM for etch & deposition. The aligner station is, for example, a Recif Technologies pre-aligner or a TDK wafer alignment system. The process chamber is, for example, a CVD chamber, an etching chamber or an EUV scanner.

As shown in the FIG. 1, during transferring the wafer, a Fan Filter Unit (FFU) 800 is used to provide descending airflow. The FFU 800 is a self-contained air filtration system that provides clean, laminar airflow in cleanrooms, wafer Fabs, and FOU P storage areas. It plays a critical role in contamination control by continuously removing airborne particles and maintaining ISO-class cleanroom standards. The FFU 800 pulls in ambient air. Then, a pre-filter is used to remove large particles. Next, a HEPA/ULPA Filter is used to removes 99.999% of particles as small as 0.1 μm. Then, the FFU 800 blows purified air downward to maintain laminar flow. The FFU 800 could prevent wafer defects caused by airborne particles, ensures high-yield production by maintaining ultra-clean environments, supports the FOUP storage to protect wafers before and after processing, and reduces maintenance downtime by controlling contamination levels.

As shown in the FIG. 1, the wafer handling robot 600 is a high-precision robotic system designed to transfer wafers between different semiconductor processing stations without contamination or damage. It plays a critical role in automated wafer fabrication. The wafer handling robot 600 could be, for example, a Cartesian wafer handling robot, a SCARA (Selective Compliance Articulated Robot Arm) wafer robot, a dual-arm wafer handling robot, a vacuum wafer handling robot, an edge-grip wafer handling robot, and a Bernoulli wafer handling robot.

The FOUP 100 includes a container 110, a diffuser 120 and a purge port 130. The container 110 is configured to carry a plurality of wafers. The container 110 is made of high-purity, anti-static polymers that prevent particle generation, outgassing, and electrostatic discharge (ESD). The material of the container 110 could be, polycarbonate (PC) with high durability, chemical resistance, and optical clarity, polyetherimide (PEI) with enhanced thermal stability and mechanical strength, conductive polypropylene (PP) with ESD protection and lightweight properties and polyether ether ketone (PEEK) with ultra-clean, high-temperature resistant for extreme conditions.

The diffuser 120 is a vertical airflow distribution structure inside the FOUP 100, ensuring uniform air circulation around the wafers. This prevents particle buildup, humidity condensation, and oxidation. The diffuser 120 is usually positioned along the back wall of the FOUP 100. The diffuser 120 is, for example, a perforated pillar diffuser, a filtered pillar diffuser which is integrated HEPA/ULPA, an ionized pillar diffuser with ESD Protection, or a multi-zone airflow control diffuser.

The perforated pillar diffuser is a hollow pillar with multiple small perforations for uniform airflow. The perforated pillar diffuser could distribute the clean dry air A1 (or N₂) evenly throughout the FOUP 100. The perforated pillar diffuser is simple, low-cost, and effective for standard wafer storage.

The filtered pillar diffuser integrated HEPA/ULPA contains HEPA/ULPA filtration inside the pillar. This filtered pillar diffuser could remove ultrafine particles (≥0.1 μm) before airflow reaches wafers. This filtered pillar diffuser is ideal for advanced nodes (≤5 nm, EUV lithography wafers).

The ionized pillar diffuser is an ionization system inside the pillar to neutralize static charges. The ionized pillar diffuser could prevent electrostatic discharge (ESD), which can damage wafers. The ionized pillar diffuser is used in EUV photomask handling and ultra-clean Fabs.

The multi-zone airflow control diffuser has adjustable airflow paths for different wafer zones. The multi-zone airflow control diffuser could optimize air distribution for varying wafer sensitivities. Custom airflow settings could be realized for high-precision Fabs (e.g., FinFET, GAA).

The purge port 130 is the entry point where the clean dry air (CDA) A1 (or N₂) is injected into the FOUP 100 via the diffuser 120. The purge port 130 is, for example, a standard purge port, a dual purge port, a smart dynamic purge port and an ESD-controlled purge port.

The standard purge port is a basic inlet port with a fixed flow rate. The standard purge port could provide constant low-flow CDA A1 (or N₂) injection into the FOUP 100. The standard purge port is used for standard wafer storage without strict humidity control.

The dual purge port has two ports. One port is for the CDA A1 (or N₂) input, another port is for exhaust. The dual purge port could maintain controlled airflow, and ensure efficient particle removal. The dual purge port is used for critical wafer processing areas, or EUV mask handling.

The smart dynamic purge port has real-time monitoring sensors for adjusting the flow rate based on humidity and oxygen levels. The smart dynamic purge port could reduce the CDA A1 (or N₂) consumption while maintaining ideal conditions. The smart dynamic purge port is used for high-end 3D NAND, GAA, and sub-5 nm wafer storage.

The ESD-controlled purge port includes ionized CDA injection to eliminate static buildup. The ESD-controlled purge port could prevent ESD-related defects in sensitive wafer processes. The ESD-controlled purge port is used for EUV photomasks and advanced lithography FOUPs.

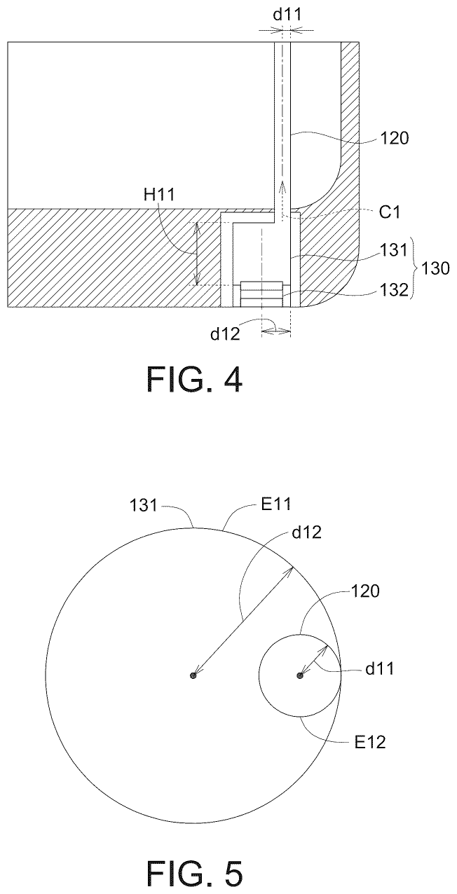

Please refer to FIGS. 3 and 4. FIG. 3 shows a cross-section view of the FOUP 100 according to one embodiment of the present disclosure. FIG. 4 shows an enlarged view of the diffuser 120 and the purge port 130 of the FOUP 100 according to one embodiment of the present disclosure. As shown in the FIG. 3, the FOUP 100 includes the container 110, the diffuser 120, the purge port 130, the door 140, the overhead hoist transport (OHT) head 150 and the wafer support 160.

As shown in the FIG. 4, the purge port 130 has a buffer room 131 and a check valve 132. The buffer room 131 in the purge port 130 is a small intermediate chamber that regulates the flow and distribution of the CDA A1 (or N₂) before it enters the FOUP 100.

The buffer room 131 could ensure a smooth and uniform flow of the CDA A1 (or N₂) into the FOUP 100, reduce airflow fluctuations that could disturb wafer stability, minimize particle disturbance to help maintain an ultra-clean wafer environment by preventing particle movement, balance the pressure difference between the FOUP 100 and the external gas supply, and ensure even gas distribution across all wafers inside the FOUP 100.

The buffer room 131 is located between the check valve 132 and the diffuser 120 inside the FOUP 100. The CDA A1 (or N₂) enters the buffer room 131 from the external gas supply. Then, the flow is regulated and stabilized before being injected into the FOUP 100. Next, the CDA A1 (or N₂) exits through the diffuser 120, distributing purified gas evenly across the wafers.

The check valve 132 is a one-way valve installed in the purge port 130 to control gas flow direction and prevent backflow contamination. The check calve 132 could stop external air or moisture from entering the FOUP 100, ensure that only the CDA A1 (or N₂) enters the FOUP 100, prevent contaminated air from re-entering the purge system, and keep the FOUP 100 at a stable pressure level, preventing fluctuations.

As shown in the FIG. 4, the diffuser 120 is fully overlapped with the buffer room 131. Therefore, the diffuser 120 and the buffer room 131 form a straight air flow channel C1.

Please refer to FIGS. 4 and 5. FIG. 5 shows a top view of the diffuser 120 and the buffer room 131 of the FOUP 100. As shown in the FIGS. 4 and 5, a first radius d11 of the diffuser 120 is less than a second radius d12 of the buffer room 131, so that the diffuser 120 is fully overlapped with the buffer room 131 and the straight air flow channel C1 could be formed from the buffer room 131 to the diffuser 120.

In one embodiment, the second radius d12 is, for example, larger than 1 mm and less than 50 mm. A ratio of the first radius d11 to the second radius d12 is, for example, between 0.3 to 1.

A height H11 of the buffer room 131 is, for example, larger than 1 mm and less than 100 mm. A ratio of the height H11 of the buffer room 131 to the second radius d12 is, for example, larger than 1. A ratio of a height H11 of the buffer room 131 to the second radius d12 is, for example, less than 5.

In the example shown in the FIGS. 4 and 5, a circular edge E11 of the buffer room 131 and a circular edge E 12 of the diffuser 120 are tangent.

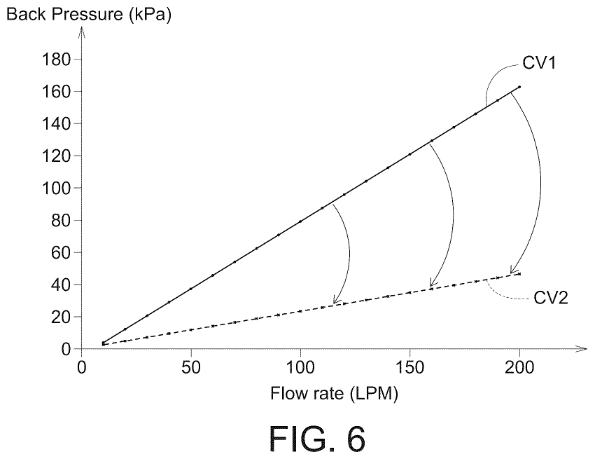

Please refer to FIG. 6, which shows a back pressure curve CV1 for a FOUP without the straight air flow channel C1 and a back pressure curve CV2 for the FOUP 100 with the straight air flow channel C1. The back pressure is proportional to the flow rate. Compared with the back pressure curve CV1, at the same flow rate, the back pressure of the back pressure curve CV2 can be much lower, due to the straight air flow channel C1.

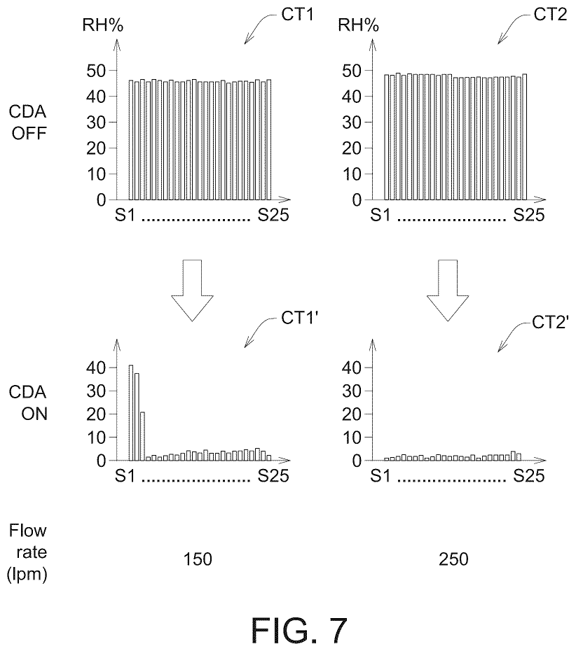

Please refer to FIG. 7, which shows humidity control for different FOUPs. Chart CT1 is a humidity distribution of wafers S1 to S25 before CDA injection in a FOUP without the straight air flow channel C1. Chart CT1′ is the humidity distribution of wafer S1 to wafer S25 during CDA injection in the FOUP without the straight air flow channel C1. As shown in the chart CT 1′, there is still quite high humidity at the wafer S1.

The high humidity at the wafer S1 may be lowered by providing an air curtain (not shown) of CDA at the opening of the FOUP. However, the air curtain requires at least 350 lpm of CDA.

Chart CT2 is the humidity distribution of wafer S1 to wafer S25 before CDA injection in the FOUP 100 with the straight air flow channel C1. Chart CT2′ is the humidity distribution of wafer S1 to wafer S25 during CDA injection in the FOUP 100 with the straight air flow channel C1. As shown in the chart CT2′, only 250 lpm of CDA is needed to achieve good humidity control on the wafers S1 to S25. The air curtain is not needed for the FOUP 100 with the straight air flow channel C1.

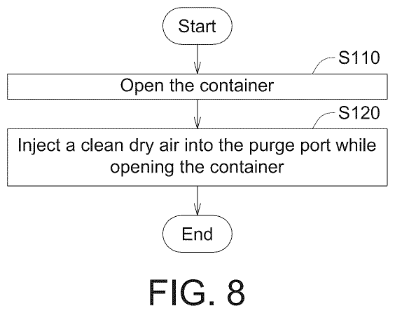

Please refer to FIG. 8, which shows a flowchart of a controlling method for the FOUP 100. The controlling method for the FOUP 100 includes, for example, steps S110 and S120. In the step S110, the container 110 is opened. Then, in the step S120, the clean dry air A1 is injected into the purge port 120 while opening the container 110. Due to the design of the buffer room 131 in the purge port 130, there is no need to provide any air curtain at the opening of FOUP 100. The flow rate of the clean dry air A1 injected into the purge port 120 is, for example, larger than 200 lpm and lower than 300 lpm.

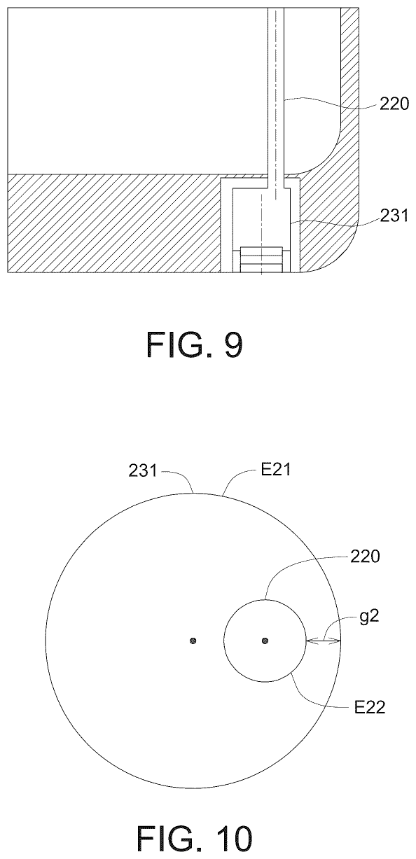

Please refer to FIGS. 9 and 10. FIG. 9 shows an enlarged view of a diffuser 220 and a buffer room 231 according to another embodiment of the present disclosure. FIG. 10 shows a top view of the diffuser 220 and the buffer room 231 according to another embodiment of the present disclosure. As shown in the FIG. 9, a circular edge E21 of the buffer room 231 is not tangent to a circular edge E22 of the diffuser 220 are offset by a gap g2.

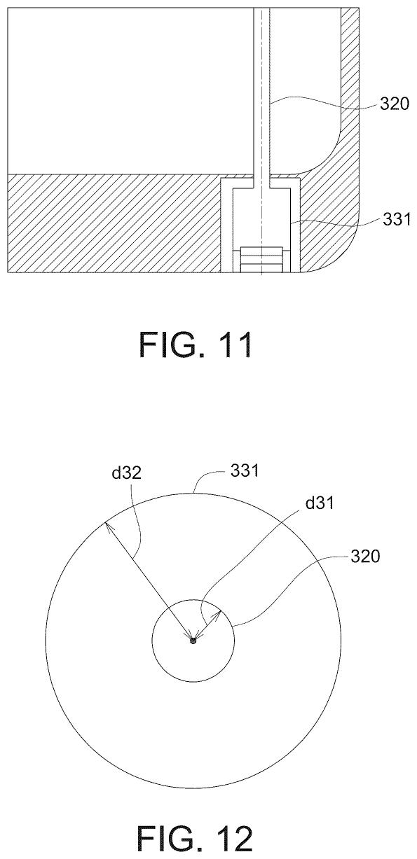

Please refer to FIGS. 11 and 12. FIG. 11 shows an enlarged view of a diffuser 320 and a buffer room 331 according to another embodiment of the present disclosure. FIG. 12 shows a top view of the diffuser 320 and the buffer room 331 according to another embodiment of the present disclosure. As shown in the FIG. 12, a circular edge E31 of the buffer room 331 and a circular edge E32 of the diffuser 320 are concentric circles.

According to the present disclosure, the diffuser 120 (or 220, 320) is fully overlapped with the buffer room 131 (or 231, 331), so the diffuser 120 (or 220, 320) and the buffer room 131 (or 231, 331) form the straight air flow channel C1 to generate a rapid air flow toward the opening of the FOUP 100. As such, the moisture could be prevented from entering the FOUP 100. There is no need to provide any air curtain at the opening of FOUP 100, and only 200 to 300 lpm of the CDA A1 is needed to achieve good humidity control on the wafers.

According to one example embodiment, a front opening unified pod (FOUP) is provided. The FOUP comprises a container, a diffuser and a purge port. The container is configured to carry a plurality of wafers. The diffuser is disposed inside the container. The purge port is disposed in a bottom plane of the container. The purge port has a buffer room. The diffuser is fully overlapped with the buffer room.

Based on the FOUP described in the previous embodiments, a first radius of the diffuser is less than a second radius of the buffer room.

Based on the FOUP described in the previous embodiments, the second radius is larger than 1 mm.

Based on the FOUP described in the previous embodiments, the second radius is less than 50 mm.

Based on the FOUP described in the previous embodiments, a height of the buffer room is larger than 1 mm.

Based on the FOUP described in the previous embodiments, a height of the buffer room is less than 100 mm.

Based on the FOUP described in the previous embodiments, a ratio of a height of the buffer room to the second radius is larger than 1.

Based on the FOUP described in the previous embodiments, a ratio of the first radius to the second radius is between 0.3 to 1.

Based on the FOUP described in the previous embodiments, a ratio of a height of the buffer room to the second radius is less than 5.

According to one example embodiment, a front opening unified pod (FOUP) is provided. The FOUP comprises a container, a diffuser and a purge port. The container is configured to carry a plurality of wafers. The diffuser is disposed inside the container. The purge port is disposed in a bottom plane of the container. The purge port has a buffer room. The diffuser and the buffer room form a straight air flow channel.

Based on the FOUP described in the previous embodiments, a first radius of the diffuser is less than a second radius of the buffer room.

Based on the FOUP described in the previous embodiments, the second radius is larger than 1 mm.

Based on the FOUP described in the previous embodiments, the second radius is less than 50 mm.

Based on the FOUP described in the previous embodiments, a height of the buffer room is larger than 1 mm.

Based on the FOUP described in the previous embodiments, a height of the buffer room is less than 100 mm.

Based on the FOUP described in the previous embodiments, a ratio of a height of the buffer room to the second radius is larger than 1.

Based on the FOUP described in the previous embodiments, a ratio of a height of the buffer room to the second radius is less than 5.

Based on the FOUP described in the previous embodiments, a ratio of the first radius to the second radius is between 0.3 to 1.

According to one example embodiment, a controlling method for a front opening unified pod (FOUP) is provided. The FOUP comprises a container, a diffuser and a purge port. The container is configured to carry a plurality of wafers. The diffuser is disposed inside the container. The purge port is disposed in a bottom plane of the container. The purge port has a buffer room. The diffuser and the buffer room form a straight air flow channel. The controlling method comprises: opening the container; and injecting a clean dry air into the purge port while opening the container. A flow rate of the clean dry air injected into the purge port is larger than 200 lpm.

Based on the controlling method for the FOUP described in the previous embodiments, the flow rate of the clean dry air injected into the purge port is lower than 300 lpm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A front opening unified pod (FOUP), comprising:
a container, configured to carry a plurality of wafers;
a diffuser, disposed inside the container; and
a purge port, disposed in a bottom plane of the container, wherein the purge port has a buffer room, and the diffuser is fully overlapped with the buffer room.

2. The FOUP according to claim 1, wherein a first radius of the diffuser is less than a second radius of the buffer room.

3. The FOUP according to claim 2, wherein the second radius is larger than 1 mm.

4. The FOUP according to claim 2, wherein the second radius is less than 50 mm.

5. The FOUP according to claim 2, wherein a height of the buffer room is larger than 1 mm.

6. The FOUP according to claim 2, wherein a height of the buffer room is less than 100 mm.

7. The FOUP according to claim 2, wherein a ratio of a height of the buffer room to the second radius is larger than 1.

8. The FOUP according to claim 2, wherein a ratio of the first radius to the second radius is between 0.3 and 1.

9. The FOUP according to claim 2, wherein a ratio of a height of the buffer room to the second radius is less than 5.

10. A front opening unified pod (FOUP), comprising:
a container, configured to carry a plurality of wafers;
a diffuser, disposed inside the container; and
a purge port, disposed in a bottom plane of the container, wherein the purge port has a buffer room, and the diffuser and the buffer room form a straight air flow channel.

11. The FOUP according to claim 10, wherein a first radius of the diffuser is less than a second radius of the buffer room.

12. The FOUP according to claim 11, wherein the second radius is larger than 1 mm.

13. The FOUP according to claim 11, wherein the second radius is less than 50 mm.

14. The FOUP according to claim 11, wherein a height of the buffer room is larger than 1 mm.

15. The FOUP according to claim 11, wherein a height of the buffer room is less than 100 mm.

16. The FOUP according to claim 11, wherein a ratio of a height of the buffer room to the second radius is larger than 1.

17. The FOUP according to claim 11, wherein a ratio of a height of the buffer room to the second radius is less than 5.

18. The FOUP according to claim 11, wherein a ratio of the first radius to the second radius is between 0.3 and 1.

19. (canceled)

20. (canceled)

21. A front opening unified pod (FOUP), comprising:
a container, configured to carry a plurality of wafers;
a diffuser, disposed inside the container; and
a purge port, disposed in a bottom plane of the container, wherein the purge port has a buffer room, and a first radius of the diffuser is less than a second radius of the buffer room.

22. The FOUP according to claim 21, wherein the second radius is larger than 1 mm.
